(19) United States
(12) Patent Application Publication
(10) Pub. No.: US 2013/0221463 A1
(43) Pub. Date: Aug. 29, 2013

(54) SOLID-STATE IMAGING ELEMENT

(71) Applicant: Yutaka OKADA, Kanagawa-ken (JP)

(72) Inventor: Yutaka OKADA, Kanagawa-ken (JP)

(73) Assignee: Kabushiki Kaisha Toshiba, Tokyo (JP)

(21) Appl. No.: 13/564,933

(22) Filed: Aug. 2, 2012

(30) Foreign Application Priority Data
Feb. 27, 2012 (JP) 2012-039473

(51) Int. Cl. H01L 31/0352

(52) U.S. Cl. 257/431; 257/E31.032

(57) ABSTRACT

According to one embodiment, a solid-state imaging element, includes a plurality of impurity regions provided with a prescribed interval, each of the impurity regions acting as a channel for transferring charges, wherein the impurity region has a trapezoid shape in which bases is perpendicularly directed to a charge transfer direction, a width of a first base of the bases at a transferring side is larger than a width of a second base of the bases at a receiving side.

### CROSS REFERENCE TO RELATED APPLICATION

This application is based upon and claims the benefit of priority from prior Japanese Patent Application No. 2012-039473, filed on Feb. 27, 2012, the entire contents of which are incorporated herein by reference.

### FIELD

Exemplary embodiments described herein generally relate to a solid-state imaging element.

### BACKGROUND

In a solid-state imaging element which performs charge transfer, a potential gradient is provided in an impurity region as a charge transfer channel to act as a driving force for the charge transfer. The potential gradient is obtained by varying an impurity concentration in the impurity region.

As a method for changing the impurity concentration, the impurity region is divided into a plurality of portions and each of portions is implanted with impurity by changing a number of implantation processes, conventionally.

However, increasing a number of resist mask processes for changing impurity-implantation region and increasing impurity-implantation processes are pointed out as problems.

On the other hand, a method mentioned below is proposed to the process mentioned above. A pattern shape of a resist mask is designed to form a comb-shape such as a periodical rectangle shape to make periodically thin the impurity region, so that narrow channel effect is generated.

Generation of narrow channel effect causes to deplete the generated portion in the impurity region to lower a carrier concentration in the portion. The impurity region can be formed by one impurity-implantation using the method mentioned above.

However, there is a problem that a potential gradient is hardly provided in the rectangle shape mentioned above, because the width of the impurity region is constant.

### BRIEF DESCRIPTION OF THE DRAWINGS

FIGS. 1A, 1B, 1C are a schematic plane view, a schematic cross-sectional view and an electrical potential distribution diagram, respectively, showing a structure of an impurity region in a channel region of a solid-state imaging element according to a first embodiment;

FIGS. 2A, 2B are a schematic plane view and an electrical potential distribution diagram, respectively, showing a structure of an impurity region in a channel region of a solid-state imaging element according to a second embodiment;

FIGS. 3A, 3B are a schematic plane view and an electrical potential distribution diagram, respectively, showing a structure of an impurity region in a channel region of another solid-state imaging element according to the second embodiment;

FIGS. 4A, 4B, 4C are a schematic plane view, a schematic cross-sectional view and an electrical potential distribution diagram, respectively, showing a structure of an impurity region in a channel region of a solid-state imaging element according to the third embodiment;

FIG. 5 is a schematic plane view showing a structure of a channel region in a solid-state imaging element according to a fourth embodiment;

FIG. 6 is a schematic plane view showing a structure of a constitution of a solid-state imaging element according to a fifth embodiment;

FIG. 7 is a schematic plane view showing a structure of an impurity region in a photoelectric conversion unit of the solid-state imaging element according to the fifth embodiment;

FIG. 8 is a schematic plane view showing a structure of an impurity region in a charge accumulation unit of the solid-state imaging element according to the fifth embodiment;

FIG. 9 is a schematic plane view showing a structure of an impurity region in a charge transfer unit of the solid-state imaging element according to the fifth embodiment.

### DETAILED DESCRIPTION

According to one embodiment, a solid-state imaging element, includes a plurality of impurity regions provided with a prescribed interval, each of the impurity regions acting as a channel for transferring charges, wherein the impurity region has a trapezoid shape in which bases is perpendicularly directed to a charge transfer direction, a width of a first base of the bases at a transferring side is larger than a width of a second base of the bases at a receiving side.

Embodiments will be described below in detail with reference to the attached drawings mentioned above. Throughout the attached drawings, similar or same reference numerals show similar, equivalent or same components, and the explanation is not repeated.

### First Embodiment

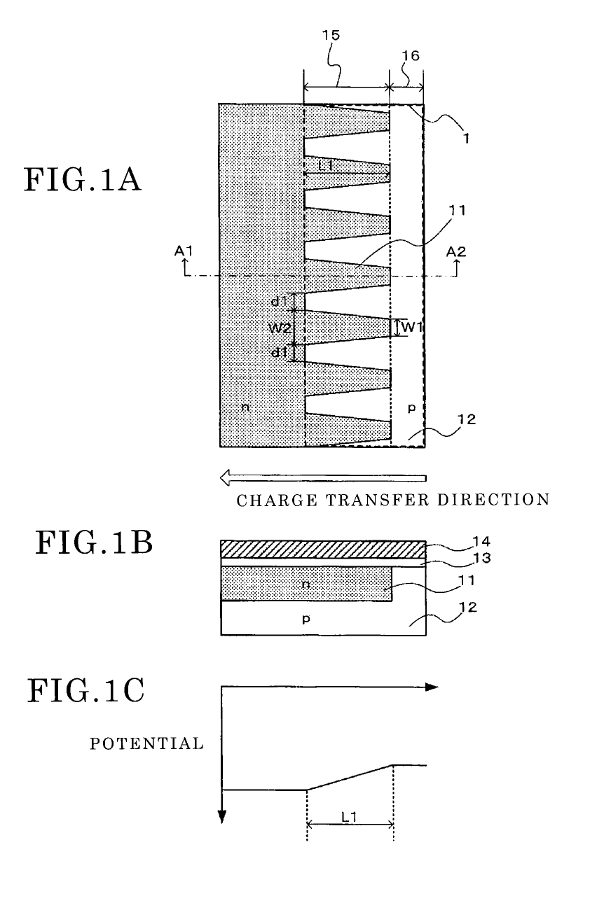

FIG. 1 shows a structure of a channel region in a solid-state imaging element.

FIG. 1A is a schematic plane view showing a structure of n-type impurity regions 11, each of the n-type impurity regions 11 is a trapezoid shape, provided in a channel region 1 including a trapezoidal pattern of the solid-state imaging element according to a first embodiment.

The n-type impurity regions 11 are provided by performing only one ion-implantation process on a p-type substrate 12.

The n-type impurity regions 11 in this embodiment constitute a trapezoidal pattern in which a trapezoid shape is repeatedly formed. Each of the n-type impurity regions 11 includes the trapezoid shape in which a width of the trapezoid shape is wider to a charge transfer direction.

As shown in FIG. 1A, the trapezoidal pattern in which seven are provided. Each of the trapezoid shapes has a width of a transferring side W1 and a receiving side W2 where W2 is wider than W1. The trapezoid shapes are lined with a prescribed interval. Both the transferring side and the receiving side are bases of the trapezoid shape, and a height of the trapezoid shape is corresponded to the charge transfer direction.

The width of the transferring side W1 is set to be a width which narrow channel effect is generated in the n-type impurity region 11. On the other hand, a portion of the n-type impurity region 11 is depleted to lower the electrical potential of the portion when the narrow channel effect is generated.

FIG. 1B is a schematic cross-sectional view showing the channel region 1 taken along the A1-A2 line as shown in FIG. 1A.

An n-type impurity region 11 is formed on a p-type substrate 12. An insulating film 13 is formed above the n-type impurity region 11, and an electrode 14 to which gate voltage is applied on the insulating film 13. The gate voltage controls charge transfer.

FIG. 1C is an electrical potential distribution diagram showing an electrical potential distribution of the impurity region 11 along the A1-A2 line as shown in FIG. 1A.

A width of the n-type impurity region 11 is gradually widened to the transfer direction to weaken also narrow channel effect to the transfer direction. As a result, a carrier concentration of the n-type impurity region 11 is gradually increased. In such a manner, potential gradient is formed in the n-type impurity region 11 along the A1-A2 line as shown in FIG. 1C.

A region including the potential gradient is called as a potential gradient region 15 with a length L1. Here, the length L1 of the potential gradient region 15 is equal to a height of each trapezoid shape in the trapezoidal pattern. Further, a non-implanted region in the channel region is called as a barrier region 16 which has functions of retaining charges under the channel and blocking reverse charge flow in a charge transfer process. Further, the barrier region 16 is configured in a range where the narrow channel effect in the potential gradient region 15 can be generated.

The narrow channel effect in the n-type impurity region is widely generated in a case that a receiving side of the charges region, which is equals to W2, is narrower, so that a tilt of the potential gradient of the n-type impurity region is enlarged. A charge transfer time passing in the channel region 1 is shorter in the case that a ratio of the potential gradient region 15 is larger in the channel region 1.

On the other hand, a dynamic range of a pixel in the solid-state imaging element is wider in a case that the potential of the barrier region 16 is higher and an area of the n-type impurity region 1 is larger. The potential can be adjusted due to the narrow channel effect using the trapezoidal pattern. Further, the potential gradient in the trapezoid shape disappears to lower a charge transfer rate when the difference between the width W2 of the receiving side and the width W1 of the transferring side.

### Second Embodiment

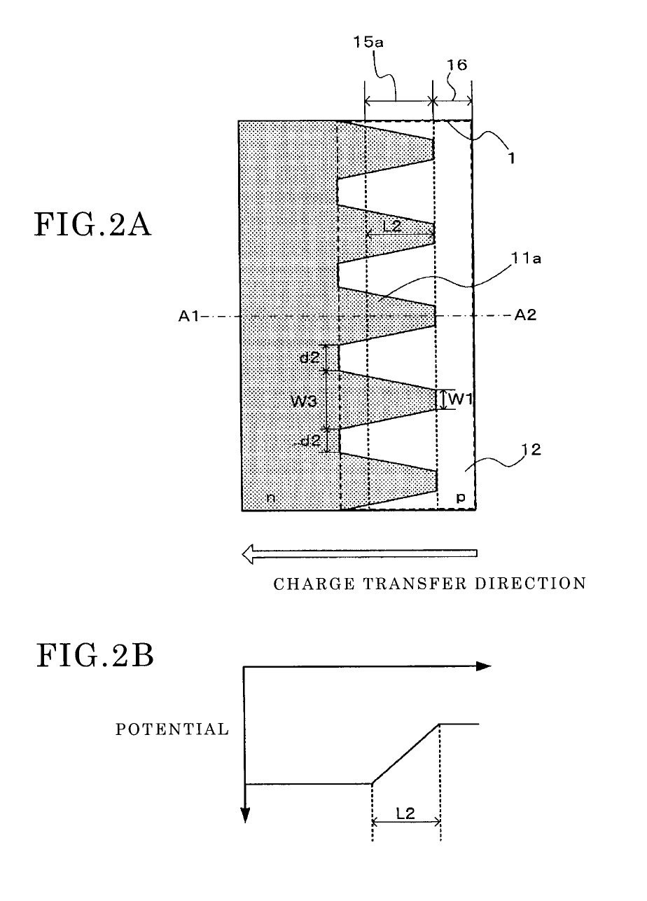

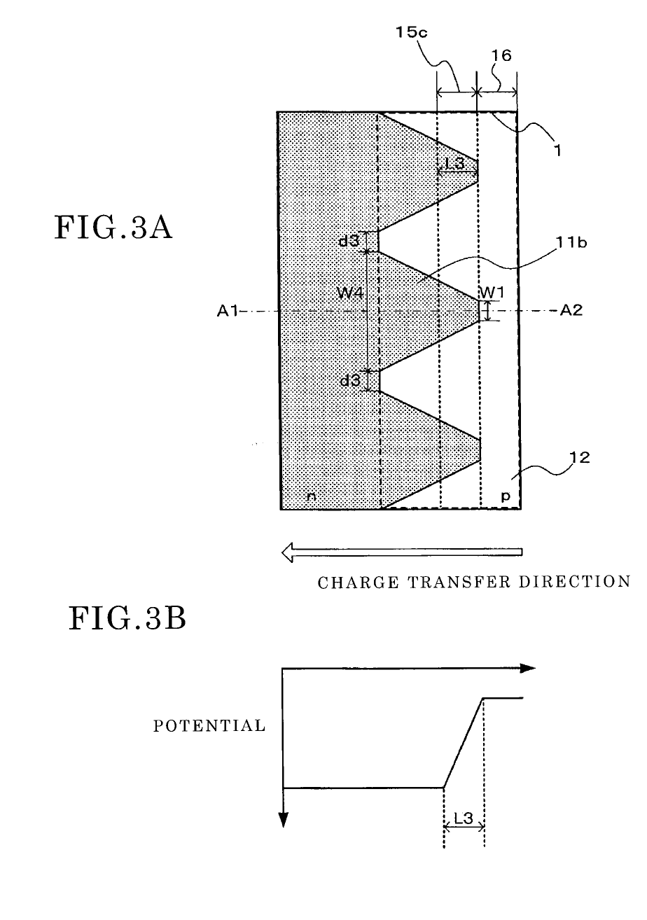

FIGS. 2A, 2B, 3A, 3B show examples in each of which a width of a receiving side is widened to retain a narrow channel effect of a trapezoid shape of an n-type impurity region as a second embodiment. In the example, an area continuously shifting a potential gradient is widened to adjust a dynamic range while increasing a charge transfer rate.

As shown in FIG. 2A, a trapezoidal pattern in which five trapezoid shapes are provided. Each of the trapezoid shapes has a width W1 of a transferring side and a width W3 of a receiving side where W3 is wider than W1. The trapezoid shapes are lined with a prescribed interval d2. Here, the width W3 of the receiving side is formed to be wider than the width W2 of the receiving side in the first embodiment as shown in FIG. 1A.

As shown in FIG. 3A, a trapezoidal pattern in which three trapezoid shapes are provided. Each of the trapezoid shapes has a width W1 of a transferring side and a width W4 of a receiving side where W4 is wider than W1. The trapezoid shapes are lined with a prescribed interval d3. Here, the width W4 of the receiving side is formed to be wider than the width W3 of the receiving side in the second embodiment as shown in FIG. 2A.

FIG. 2B is a schematic cross-sectional view showing an electrical potential distribution of an impurity region 11a taken along the A1-A2 line as shown in FIG. 2A.

In such a case, a range in which narrow channel effect is generated becomes narrower, as the width W3 of the receiving side is wider. Further, a length L2 of a potential gradient 15a is shorter than the length L1 of the potential gradient 15 as shown in FIG. 1C. In other words, the length L2 of the potential gradient 15a is shorter than a height of each trapezoid shape in a trapezoidal pattern. Accordingly, a portion without a potential gradient is increased so that a charge transfer time is longer.

As similarly, FIG. 3B is a schematic cross-sectional view showing an electrical potential distribution of an impurity region 11b taken along the A1-A2 line as shown in FIG. 3A.

In such a case, the width W4 of the receiving side is further wider. As a result, a length L3 of a potential gradient 15b is further shorter than the length L2 of the potential gradient 15a as shown in FIG. 2B. Consequently, a charge transfer time is further longer.

As mentioned above, the charge transfer time has a trade-off relation to the dynamic range. Therefore, sizes and a number of the trapezoidal shapes in the trapezoidal pattern are optimized in consideration with priority between the charge transfer time and the dynamic range or the like in this embodiment.

### Third Embodiment

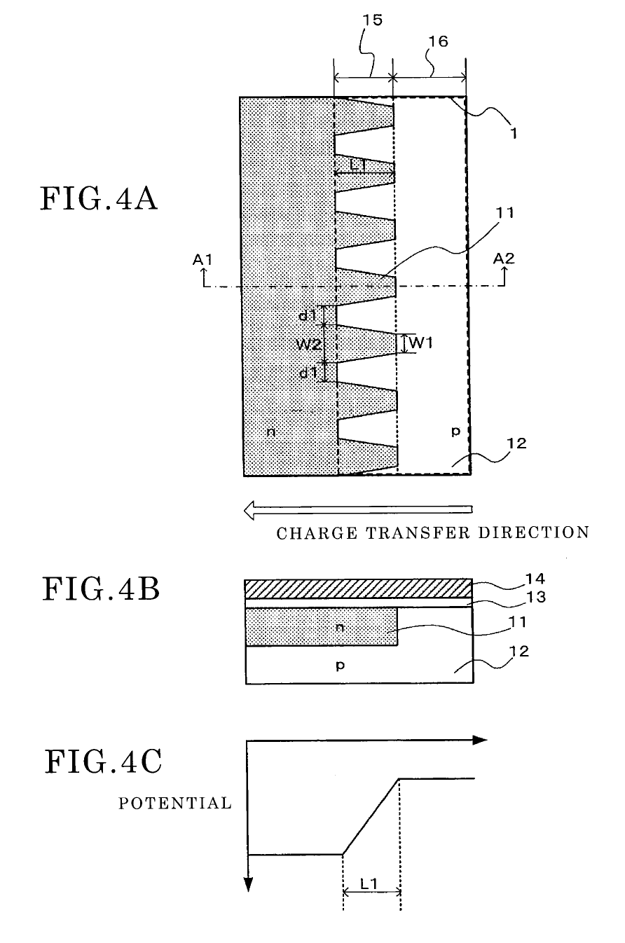

As a third embodiment, FIGS. 4A, 4B, 4C show an example in which a length L1 of a potential gradient 15 is changed. In the example, narrow channel effect generated in a barrier region 16 is changed to adjust a potential of the barrier region 16. Here, the length L1 of the potential gradient 15 is equal to a height of a trapezoid shape in a trapezoidal pattern.

In such a case, the potential of the barrier region 16 as shown in FIG. 4C can be higher than the potential of the barrier region 16 as shown in FIG. 1C.

In such a manner, the potential of the barrier region 16 is changed by adjusting a number of trapezoid shapes and the length of the potential gradient region 15 in each trapezoid shape of the trapezoidal pattern, so that the dynamic range of the solid-state imaging element can be adjusted.

In the embodiments mentioned above, the n-type impurity region is formed on the p-type substrate, however, the p-type impurity region can be formed on the n-type substrate, reversely.

### Fourth Embodiment

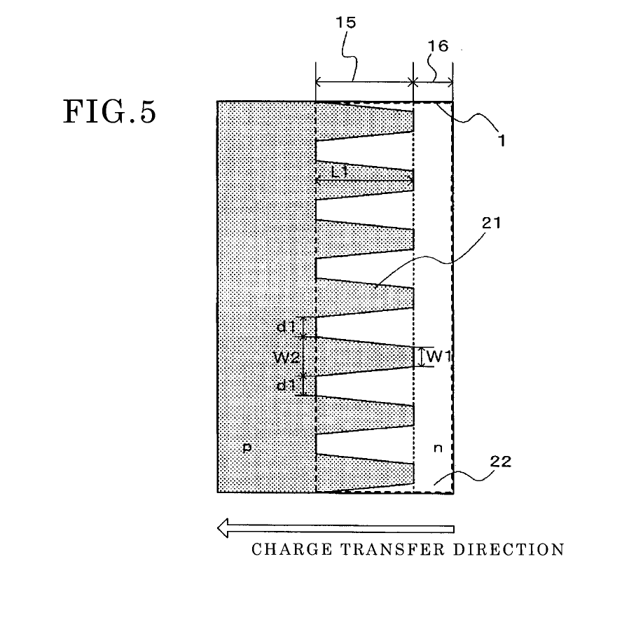

FIG. 5 is a schematic plane view showing a structure in which a p-type impurity region 21 is formed on an n-type substrate 22 according to a fourth embodiment. A shape of the p-type impurity region 21 is the same as the n-type impurity region 11 as shown in FIG. 1A.

### Fifth Embodiment

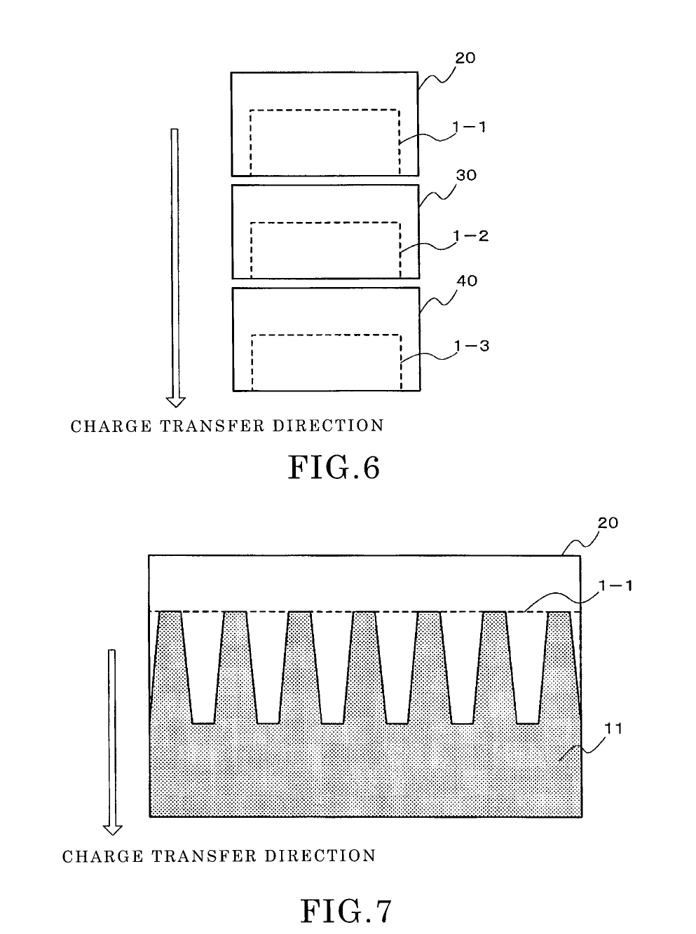

FIG. 6 is a schematic plane view showing an example of a constitution of a solid-state imaging element according to a fifth embodiment.

The solid-state imaging element in this embodiment includes a photoelectric conversion unit 20, a charge accumulation unit 30, and a charge transfer unit 40. The photoelectric conversion unit 20 generates charges corresponding to incident light intensity. The charge accumulation unit 30 accumulates the charges transferred from the photoelectric conversion unit 20. The charge transfer unit 40 transfers the charges transferred from the charge accumulation unit 30. The photoelectric conversion unit 20, the charge accumulation unit 30, and the charge transfer unit 40 are arranged along the charge transfer direction.

The photoelectric conversion unit 20 includes a channel region 1-1, the charge accumulation unit 30 includes a channel region 1-2, and the charge transfer unit 40 includes a channel region 1-3, respectively.

A trapezoidal pattern is included in an impurity region of each channel region as shown in FIGS. 1-5 in this embodiment.

FIG. 7 is a schematic plane view showing the n-type impurity region 11 in the channel region 1-1 of the photoelectric conversion unit 20 as shown in FIG. 1A.

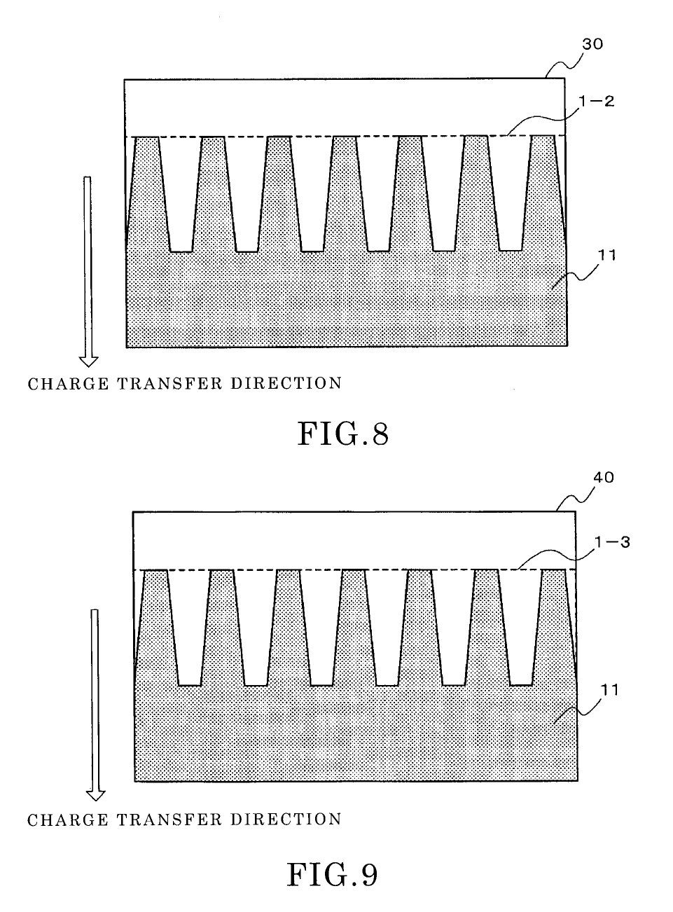

FIG. 8 is a schematic plane view showing the n-type impurity region 11 of the channel region 1-2 in the charge accumulation unit 30 as shown in FIG. 1A.

FIG. 9 is a schematic plane view showing the n-type impurity region 11 of the channel region 1-3 in charge transfer unit 40 as shown in FIG. 1A.

A shape of the n-type impurity region of each channel region is the same in the examples mentioned above, however, it is not necessary that the shape is the same each other. The shape of the n-type impurity region of each channel region is decided on a basis of each specification.

The trapezoidal pattern, in which each of the trapezoid shapes as the impurity region transferring the charges is repeatedly arranged with a prescribed interval, is included in the solid-state imaging element. As the width of the impurity region is gradually wider to the transfer direction, narrow channel effect generated in the impurity region is also weakened to the transfer direction. Therefore, the carrier concentration in the impurity region is gradually increased. In such a manner, the impurity region can be sufficiently having the potential gradient.

A relation between the charge transfer time and the dynamic range can be optimized by adjusting the sizes and a number of the trapezoidal shapes in the trapezoidal pattern.

According to the solid-state imaging element as mentioned above, the potential gradient can be sufficiently provided in the impurity region by one impurity-implantation process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging element, comprising:
a plurality of impurity regions provided with a prescribed interval, each of the impurity regions acting as a channel for transferring charges,
wherein the impurity region has a trapezoid shape in which bases is perpendicularly directed to a charge transfer direction, a width of a first base of the bases at a transferring side is larger than a width of a second base of the bases at a receiving side.

2. The solid-state imaging element of claim 1, wherein
the width of the first base at the transferring side is arranged within a range in which narrow channel effect is generated.

3. The solid-state imaging element of claim 2, wherein
a number of the impurity regions are decided corresponding to a prescribed potential gradient of the impurity region.

4. The solid-state imaging element of claim 3, wherein
a dynamic range of the solid-state imaging element is adjusted by sizes, a number and an impurity concentration of the trapezoid shape.

5. The solid-state imaging element of claim 1, further comprising:
a barrier region contacted with the impurity region.

6. The solid-state imaging element of claim 5, wherein
the impurity region and the barrier region respectively include a reverse conductive type impurity each other.

7. The solid-state imaging element of claim 1, wherein
the impurity region is provided by one doping process.

8. The solid-state imaging element of claim 4, wherein
the impurity region has a first trapezoid as the trapezoid shape, a height of the first trapezoid is the same as a length of a potential gradient region in the first trapezoid.

9. The solid-state imaging element of claim 4, wherein
the impurity region has a second trapezoid as the trapezoid shape, a height of the second trapezoid is larger than a length of a potential gradient region in the second trapezoid.

10. The solid-state imaging element of claim 9, wherein
the impurity region has a third trapezoid as the trapezoid shape, a width of a first base of the third trapezoid at the transferring side is the same as the width of the first base of the second trapezoid at the transferring side, a width of a second base of the third trapezoid at the receiving side is wider than the width of the second base of the second trapezoid at the receiving side, a length of a potential gradient in the third trapezoid is shorter than the length of the potential gradient in the second trapezoid.

11. The solid-state imaging element of claim 4, wherein
the impurity region has a fourth trapezoid as the trapezoid shape, a first base of the fourth trapezoid at the transferring side and a second base of the fourth trapezoid at the receiving side are the same as the first base of the first trapezoid at the transferring side and the second base of the first trapezoid at the receiving side, respectively, a height of the fourth trapezoid is lower than the height of the first trapezoid and is the same as a length of a potential gradient in the fourth trapezoid.

12. The solid-state imaging element of claim 3, wherein
the solid-state imaging element is provided at least one selected from a photoelectric conversion unit, a charge accumulation unit and a charge transfer unit, where the photoelectric conversion unit generates charges corresponding to incident light intensity, the charge accumulation unit accumulates the charges transferred from the photoelectric conversion unit and the charge transfer unit transfers the charges transferred from the charge accumulation unit.

13. The solid-state imaging element of claim 12, wherein
the photoelectric conversion unit, the charge accumulation unit, and the charge transfer unit are arranged along the charge transfer direction.
